(19) United States
(12) Patent Application Publication
(10) Pub. No.: US 2014/0002161 A1
(43) Pub. Date: Jan. 2, 2014

(54) CIRCUIT ARRANGEMENT, A RETENTION FLIP-FLOP, AND METHODS FOR OPERATING A CIRCUIT ARRANGEMENT AND A RETENTION FLIP-FLOP

(71) Applicants: Klaus von Arnim, Muenchen (DE); Stefan Bergler, Muenchen (DE)

(72) Inventors: Klaus von Arnim, Muenchen (DE); Stefan Bergler, Muenchen (DE)

(21) Appl. No.: 13/834,400

(22) Filed: Mar. 15, 2013

Related U.S. Application Data
(60) Provisional application No. 61/667,031, filed on Jul. 2, 2012.

(51) Int. Cl. H03K 3/012; H03K 3/36

(52) U.S. Cl. CPC H03K 3/012; H03K 3/36
USPC 327/202; 327/215

(57) ABSTRACT

Various aspects of this disclosure provide a circuit arrangement, including: an input; a first latch circuit coupled to the input, the first latch circuit including a first forward inverter and a first feedback inverter; a switch, wherein a first terminal of the switch is coupled to an output of the first forward inverter; a second latch circuit coupled to a second terminal of the switch; an output coupled to the second latch circuit; and an isolating circuit configured to isolate the first forward inverter from an input of the first feedback inverter.

### CROSS-REFERENCE TO RELATED APPLICATION

This application claims the benefit of U.S. provisional application No. 61/667,031 filed 2 Jul. 2012, the content of it being hereby incorporated by reference in its entirety for all purposes.

### TECHNICAL FIELD

Various aspects of this disclosure relate to a circuit arrangement, a retention flip-flop, and methods for operating a circuit arrangement and a retention flip-flop.

### BACKGROUND

Retention circuits may be used to retain a logic state (binary 1 or binary 0) when surrounding logic is switched off. These retention circuits may be implemented as retention flip-flops, wherein a selected part of the retention flip-flop may be powered on permanently, whilst another part may be controllably switched off. However, retaining logic in typical state-retention flip-flops require at least one control signal, require an additional storage node or latch circuit, and impose additional timing conditions upon wake-up, i.e., resumption of power to surrounding logic. Accordingly, typical retention flip-flops have significant area and timing overhead compared to standard flip-flops. Consequently, state-retention flip-flops with a simple control sequence and low area and timing overhead are desirable.

### SUMMARY

Various aspects of this disclosure provide a circuit arrangement. The circuit arrangement may include an input; a first latch circuit coupled to the input, the first latch circuit including a first forward inverter and a first feedback inverter; a switch, wherein a first terminal of the switch is coupled to an output of the first forward inverter; a second latch circuit coupled to a second terminal of the switch; an output coupled to the second latch circuit; and an isolating circuit configured to isolate the first forward inverter from an input of the first feedback inverter.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various aspects of this disclosure. In the following description, various aspects of this disclosure are described with reference to the following drawings, in which:

FIG. 1 shows a balloon retention flip-flop;

FIG. 2 shows a retention flip-flop in a master-slave D-flip-flop architecture;

FIG. 3 shows a circuit arrangement according to an aspect of this disclosure;

FIG. 4 shows a circuit arrangement after a control signal terminal provides a save signal to an isolating circuit according to an aspect of this disclosure;

FIG. 5 shows relative timings of signals provided by a control signal terminal and a power supply terminal according to an aspect of this disclosure;

FIG. 6 shows a circuit arrangement after a control signal terminal provides a save signal to an isolating circuit according to an aspect of this disclosure;

FIG. 7 shows a circuit arrangement after a control signal terminal provides a restore signal and when a clock terminal provides a second binary level to a switch according to an aspect of this disclosure;

FIG. 8 shows a retention flip-flop according to an aspect of this disclose;

FIG. 9 shows a retention flip-flop according to another aspect of this disclose;

FIG. 10 shows a method for operating a circuit arrangement according to an aspect of this disclosure;

FIG. 11 shows a method for operating a circuit arrangement according to another aspect of this disclosure;

FIG. 12 shows a method for operating a retention flip-flop according to an aspect of this disclosure;

FIG. 13 shows a method for operating a retention flip-flop according to another aspect of this disclosure.

### DESCRIPTION

The following detailed description refers to the accompanying drawings that show, by way of illustration, specific details and aspects of this disclosure in which the disclosure may be practiced. These aspects of the disclosure are described in sufficient detail to enable those skilled in the art to practice the disclosure. Other aspects of this disclosure may be utilized and structural, logical, and electrical changes may be made without departing from the scope of the disclosure. The various aspects of this disclosure are not necessarily mutually exclusive, as some aspects of this disclosure can be combined with one or more other aspects of this disclosure to form new aspects of this disclosure.

Retention flip-flops are flip-flops which retain there data even after surrounding logic is powered down. Most state-of-the-art retention flip-flops may be divided into two classes: Balloon retention flip-flops and Retention flip-flop in master-slave D-flip-flop architecture.

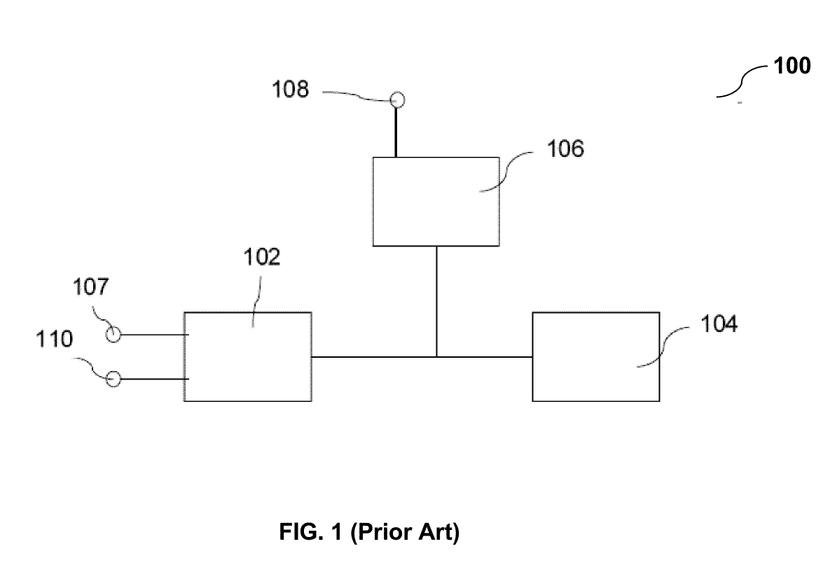

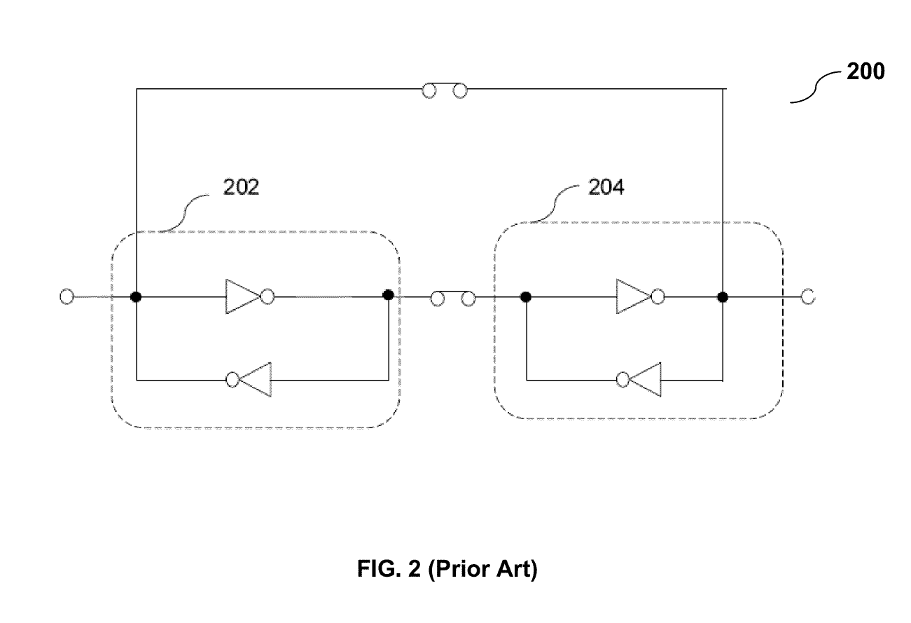

FIG. 1 shows a balloon retention flip-flop 100, and FIG. 2 shows a retention flip-flop in a master-slave D-flip-flop architecture 200 in accordance with various aspects of this disclosure.

Balloon retention flip-flops 100 may be implemented as master-slave latches 102, 104 including an additional storage node 106, or additional data preserving circuit, sometimes referred to as a “shadow” latch or “balloon” latch 106. In an implementation, the master-slave latches 102, 104 may be designed from standard, low Vₜ transistors, whilst the balloon latch 106 may be designed using weak high Vₜ transistors. The balloon latch 106 may be connected to an always on power supply 108 and may hold the register state while the leaky master-slave register latches 102, 104 are powered down in sleep mode. Balloon retention flip-flops require complicated timing for transferring data back and forth between the balloon latch 106 and the master-slave latches 102, 104 on any transition from sleep mode (namely, when master-slave latches 102, 104 are powered-down) to active mode and vice versa. By way of example, if the clock 107 is low and the master latch is open and sampling input data 110, the retained value in the balloon latch 106 is forced into the slave latch 104. However, if the clock 107 is high, the retained latch value in the balloon latch 106 may be forced into the master latch 102 and then propagates to the slave latch 104 when the clock 107 goes low. Balloon retention flip-flops also suffer from large size, power and delay related problems.

A retention flip-flop in a master-slave D-flip-flop architecture 200 may include an always-on stage, wherein either the master 202 or the slave stage 204 of the retention flip-flop 200 is or are powered during the retention phase (namely, when data is stored or saved in either one of the master 202 or slave 204 stages). Apart from small speed degradation, this implementation may allow for an area- and power-efficient implementation. However, wake-up these types of retention flip-flops have special constraints with respect to the clock state, such as, requiring the clock to be “0” when getting out of the retention mode.

Consequently, state-retention flip-flops with a simple control sequence and low area and timing overhead are desirable.

Various aspects of this disclosure provide a circuit arrangement.

Various aspects of this disclosure provide a retention flip-flop.

The word “exemplary” is used herein to mean “serving as an example, instance, or illustration”. Any aspect of this disclosure or design described herein as “exemplary” is not necessarily to be construed as preferred or advantageous over other aspects of this disclosure or designs.

The word “circuit” is used herein to mean any kind of a logic implementing entity, which may be special purpose circuitry or a processor executing software stored in a memory, firmware, or any combination thereof. Thus, in an aspect of this disclosure, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Different circuits can thus also be implemented by the same component, e.g. by a processor executing two different programs.

In an aspect of this disclosure, the circuit arrangement and the retention flip-flop may include an always-on slave stage (or an always-on latch circuit) which is allowed to be re-activated independent of the clock state. Accordingly, the circuit arrangement and the retention flip-flop may be capable of clock-state-independent wake-up. The circuit arrangement and the retention flip-flop may allow writing of a retained logic state from the always-on slave stage (or always-on latch circuit) into the master stage, regardless of the clock state and with low timing and area overhead.

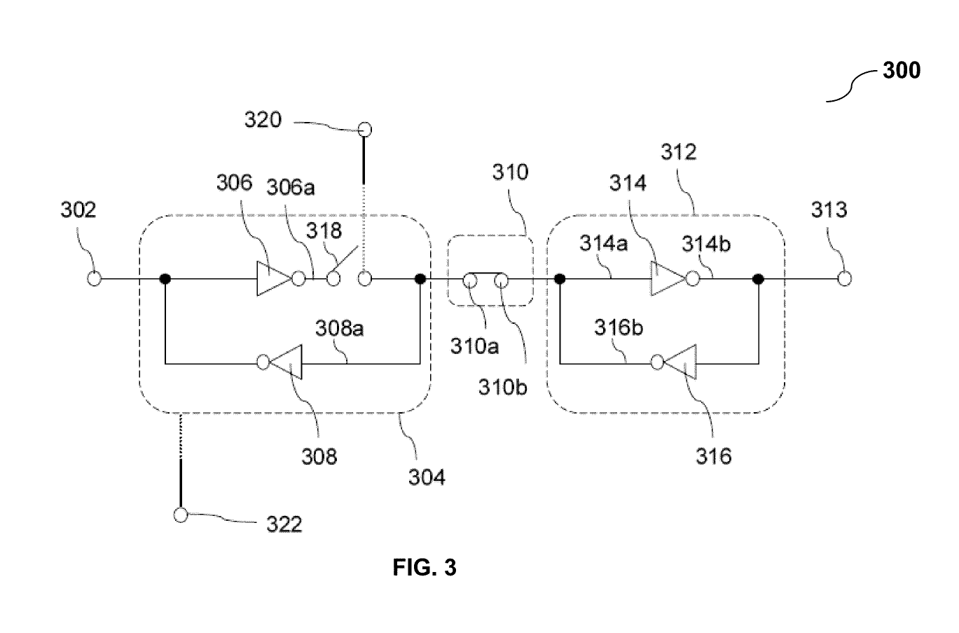

FIG. 3 shows a circuit arrangement 300 according to an aspect of this disclosure. The circuit arrangement 300 may include an input 302, which may be coupled to a first latch circuit 304. As used herein, terms concerning coupling, connection, communication, or inter-connection refer to a relationship wherein features communicate with one another either directly or indirectly through intervening structures, unless expressly described otherwise. Accordingly, the input 302 may be electrically connected to the first latch circuit 304.

The first latch circuit 304 may include a first forward inverter 306 and a first feedback inverter 308. Each inverter 306 and 308 may include a single transistor, e.g. a single metal oxide semiconductor (MOS) transistor, e.g. a single NMOS transistor, a single PMOS transistor coupled with a resistor, or bipolar junction transistors (BJT) in either a resistor-transistor logic (RTL) or a transistor-transistor logic (TTL) configuration, or at least one complementary MOS (CMOS) transistor, or any combination thereof Each inverter 306, 308 may be an either an active-high or an active-low latch inverter. In an aspect of this disclosure, each inverter 306, 308, may have two input terminals, and the input 302 may be connected to at least one of the inputs of the first forward inverter 306. In like manner, the output 306a of the first forward inverter 306 may be coupled to at least one of the inputs of the first feedback inverter 308.

The circuit arrangement 300 may include a switch 310, wherein a first terminal 310a (which may also be referred to as first controlled terminal 310a) of the switch 310 is coupled to an output 306a of the first forward inverter 306. The switch 310 may include at least one NMOS transistor, at least one PMOS transistor, at least one bipolar junction transistor, at least one CMOS transistor, a transmission gate, or any combination thereof.

In various aspects of this disclosure, the circuit arrangement 300 may include a second latch circuit 312 coupled to a second terminal 310b (which may also be referred to as second controlled terminal 310b) of the switch 310. The further features described above with reference to the first latch circuit 304 are equally applicable, and hereby restated, in respect of the second latch circuit 312.

The circuit arrangement 300 may include an output 313 coupled to the second latch circuit 312. Furthermore, the second latch circuit 312 may include a second forward inverter 314 and a second feedback inverter 316, wherein an input 314a of the second forward inverter 314 is coupled to the second terminal 310b of the switch 310, and wherein an output 314b of the second forward inverter 314 is coupled to the output 313 and to an input of the second feedback inverter 316.

In an aspect of this disclosure, the circuit arrangement 300 may further include an isolating circuit 318 configured to isolate the first forward inverter 306 from an input 308a of the first feedback inverter 308.

In an aspect of this disclosure, the isolating circuit 318 may be included in (in other words incorporated in) or implemented by the first latch circuit 304, but may be at least partially external to each of the first forward inverter 306 and the first feedback inverter 308. For example, as shown in FIG. 3, the isolating circuit 318 may be an isolating switch, for example, a transmission gate, wherein a first terminal 318a (which may also be referred to as first controlled terminal 318a) of the isolating circuit 318 may be coupled to an output 306a of the first forward inverter 306, and wherein a second terminal 318b (which may also be referred to as second controlled terminal 318b) of the isolating circuit 318 may be coupled to the first terminal 310a of the switch 310 and the input 308a of the first feedback inverter 308.

The isolating circuit 318 may be included in e.g. the first forward inverter 306 or the first feedback inverter 308. For example, the isolating circuit 318 and the first forward inverter 306 may be implemented together as a tri-state inverter which allows an output 306a of the first forward inverter 306 to assume a high impedance state in addition to the typical 0 and 1 binary logic levels.

The isolating circuit 318 may be a circuit separate from all other features.

The isolating circuit 318 may be configured to controllably isolate the first forward inverter 306 from the input 308a of the first feedback inverter 308. Accordingly, the circuit arrangement 300 may include a control signal terminal 320 coupled to the isolating circuit 318, wherein the control signal terminal 320 may be configured to provide a control signal to the isolating circuit 318 to controllably isolate the first forward inverter 306 from the input 308a of the first feedback inverter 308.

In various aspects of this disclosure, the control signal terminal 320 may be configured to provide a restore signal to the isolating circuit 318 to isolate the first forward inverter 306 from the input 308a of the first feedback inverter 308. The control signal terminal 320 may be further configured to provide a save signal to the isolating circuit 318 to couple the first forward inverter 306 to the input 308a of the first feedback inverter 308. The save and restore signals may be typical binary logic signals “0” (“low”) and “1” (“high”). The save and restore signals may each be analog signals of a predetermined voltage and/or current.

The circuit arrangement 300 may include a power supply terminal 322 coupled to the first latch circuit 304. The power supply terminal 322 may be configured to selectively supply power to the first latch circuit 304. Consequently, the first latch circuit 304 may be supplied with electric power during a first time period, and powered down (in other words, not supplied with electric power) at a later stage. In like manner, power to the first latch circuit 304 may be resumed after a period wherein power to the first latch circuit 304 has been turned off.

The second latch circuit 312 may be permanently electrically powered. The power supply to the second latch circuit 312 may be provided through the power supply terminal 322 or through another terminal

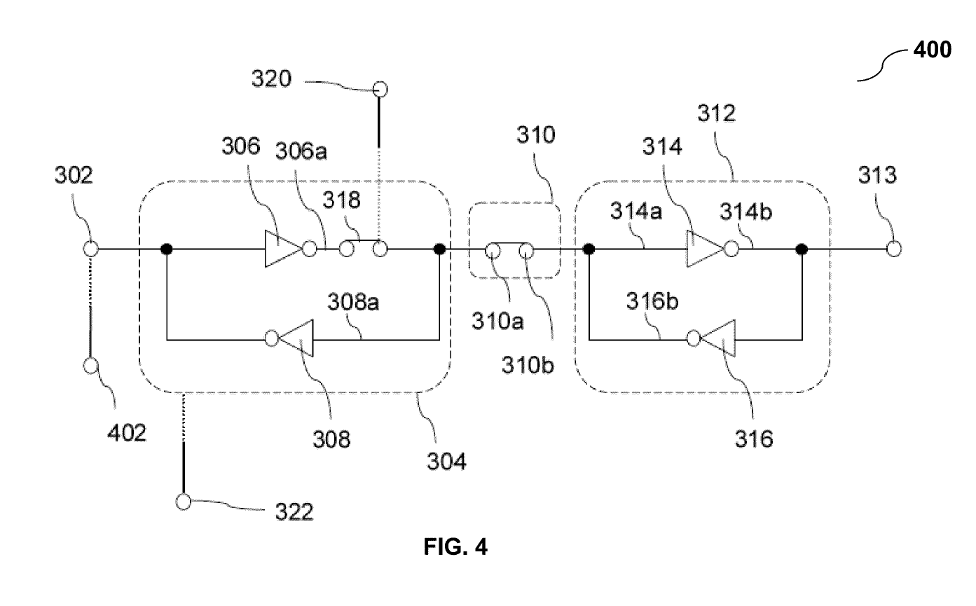

FIG. 4 shows a circuit arrangement 400 after the control signal terminal provides a save signal according to various aspects of this disclosure.

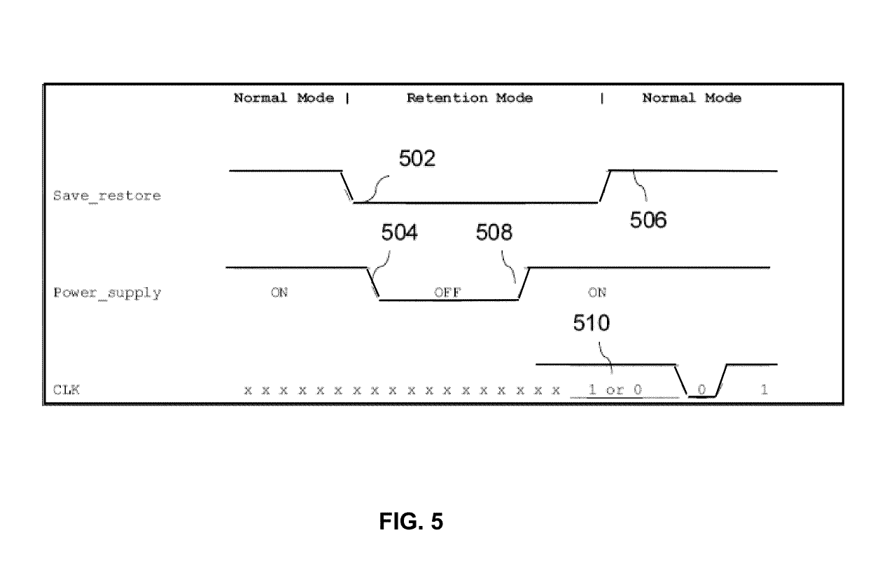

FIG. 5 shows relative timings of signals provided by the control signal terminal and the power supply terminal according to various aspects of this disclosure.

As disclosed above, the control signal terminal 320 may be configured to provide a save signal 502 to the isolating circuit 318 to couple the first forward inverter 306 to the input 308a of the first feedback inverter 308. Accordingly, the output 306a of the first forward inverter 306 may be electrically coupled to the input 308a of the first feedback inverter 308.

As shown in FIG. 4, the input 302 may be coupled to the output 313 through the first forward inverter 306, the switch 310, and the second latch circuit 312 after the control signal terminal 320 has provided the save signal 502 to the isolating circuit 318. In various aspects of this disclosure, the switch 310 may be coupled to a clock terminal, wherein a first clock level may close the switch 310 (as shown in FIG. 4), and a second clock level may open the switch 310. In an aspect of this disclosure where the clock signal supplied to the switch 310 is periodic, the switch 310 may be periodically opened and closed. Accordingly, FIG. 4 denotes the instant in time when the clock signal renders switch 310 closed.

In various aspects of this disclosure, the circuit arrangement 400 may include a logic terminal 402 coupled to the input 302. The logic terminal 402 may be additionally coupled to the output 313 through the input 302, the first forward inverter 306, the switch 310, and the second latch circuit 312 after the control signal terminal 320 has provided the save signal 502 to the isolating circuit 318 to couple the first forward inverter 306 to the input 308a of the first feedback inverter 308.

The logic terminal 402 may be configured to provide a logic state to the output 313 through the input 302, the first forward inverter 306, the switch 310, and the second latch circuit 312. In an aspect wherein the second latch circuit 312 includes a second forward inverter 314 and a second feedback inverter 316 is arranged as shown in FIG. 4, the second latch circuit 312 may be configured to store the logic state provided by the logic terminal 402 to the output 313 by at least circulating the logic state between the second forward inverter 314 and the second feedback inverter 316 of the second latch circuit 312. Accordingly, the logic state stored in the second latch circuit 312 may circulate through 314a, 314, 314b, 316, 316b, 314a, 314, and so on.

The power supply terminal 322 may be configured to disrupt power 504 to the first latch circuit 304 after the second latch circuit 312 has stored the logic state provided by the logic terminal to the output 313. Accordingly, the logic state may be propagated through the first latch circuit 304 and the switch 310 to the second latch circuit 312 and the output 313, and, e.g. subsequently, stored in the second latch circuit 312. Consequently, the logic state may be stored in the circuit arrangement 400 even when power to the first latch circuit 304 is turned off, and for as long as power to the first latch circuit 304 is turned off. Stated differently, the logic state may be isolated or retained in the second latch circuit 312 whilst the first latch circuit 304 is powered down or in sleep-mode.

The power supply terminal 322 may resume power 508 to the first latch circuit 304. In this case, the control signal terminal 320 may be configured to provide the restore signal 506 to the isolating circuit 318 to isolate the first forward inverter 306 from the input 308a of the first feedback inverter 308 after the power supply terminal 322 resumes power 508 to the first latch circuit 304.

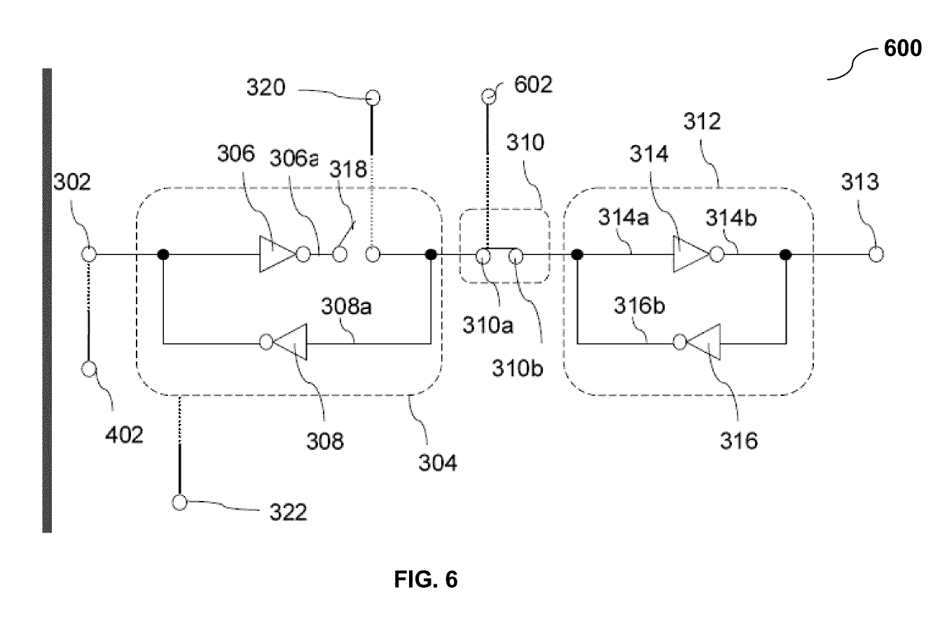

FIG. 6 shows a circuit arrangement 600 after the control signal terminal provides a restore signal according to various aspects of this disclosure.

In an aspect where the isolating circuit 318 may be included in the first latch circuit 304 but separate from the first forward inverter 306, for example, an isolating switch, such as e.g. the transmission gate 318 shown in FIG. 6, the isolating circuit 318 may be in an open position to electrically decouple the first forward inverter 306 from the input 308a of the first feedback inverter 308 after the control signal terminal 320 provides restore signal 506 to the isolating circuit 318. It would also be clear that the first forward inverter 306 is electrically decoupled from the switch 310 in this case.

In an aspect where the isolating circuit 318 may be included in either the first forward inverter 306 or the first feedback inverter 308, such as e.g. when the isolating circuit 318 and the first forward inverter 306 may be implemented together as a tri-state inverter, the output 306b of the first forward inverter 306 may assume a high impedance state to electrically decouple the first forward inverter 306 from the first feedback inverter 308 and the switch 310 after the control signal terminal 320 provides restore signal 506 to the isolating circuit 318.

The circuit arrangement 600 may include a clock terminal 602 coupled to the switch 310, the clock terminal 602 configured to supply a binary clock signal (510 of FIG. 5) including a first binary level (for example, logic level “0” (“low”)) and a second binary level (for example, logic level “1” (“high”)) to the switch 310. Alternatively, the first and second binary levels may be logic levels “1” (“high”) or “0” (“low”), respectively.

The switch 310 may be closed in response to the first binary level, whilst the switch 310 may be open in response to the second binary level. As used herein, ‘closed’ refers to the case where the first and second terminals 310a, 310b of the switch 310 are electrically coupled to each other, whilst ‘open’ refers to the case where the first and second terminals 310a, 310b of the switch 310 are electrically decoupled from each other.

An aspect of the disclosure may allow the logic state isolated (namely, retained or stored) in the second latch circuit 312 to be written into the first latch circuit 304 upon wake-up, i.e., upon resumption of power supply to the first latch circuit 304 regardless of the clock signal 510. Consequently, an aspect of this disclosure may provide for a retention flip-flop with clock-state-independent wake-up with low area and timing overhead.

Aspects of this disclosure pertaining to each of the two binary clock states will now be described in detail.

The switch 310 may be closed in response to the first binary level (as shown in FIG. 6), namely, the output 313 may be coupled to the input 302 through the second latch circuit 312, the switch 310, and the first feedback inverter 308a, 308 when the clock terminal 602 provides the first binary level 510 to the switch 310.

The logic state stored (or retained or isolated) in the second latch circuit 312 (prior to powering down the first latch circuit) may be written into the first latch circuit 304 in that the logic state may propagate from the output to the input through the second feedback inverter 316 of the second latch circuit 312, the switch 310, and the first feedback inverter 308 such that the logic state is written into the input of the first forward inverter 306.

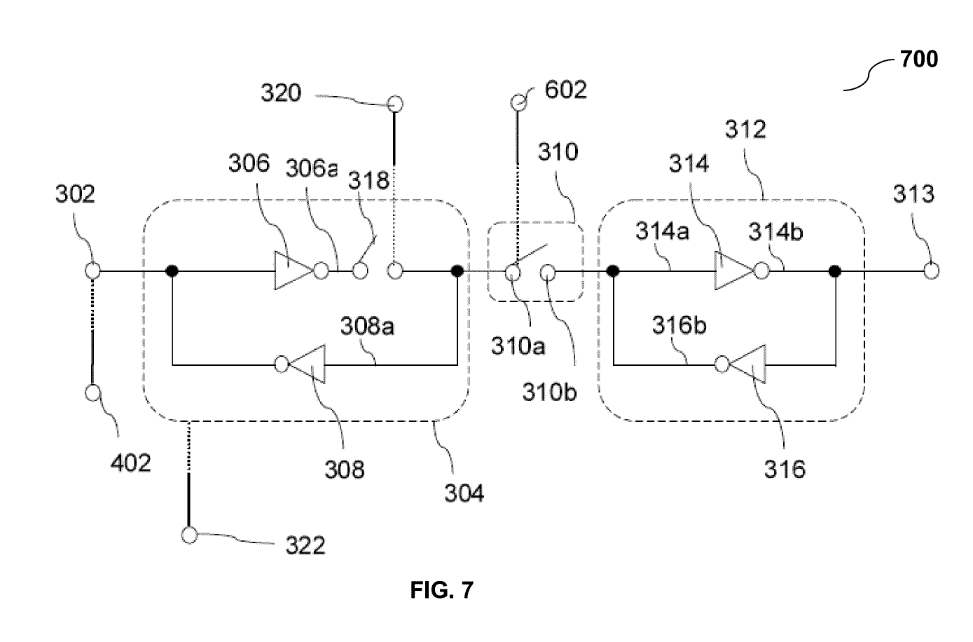

FIG. 7 shows a circuit arrangement 700 after the control signal terminal 320 provides the restore signal 506 and when the clock terminal 602 provides a second binary level 510 to the switch 310.

In an aspect of the disclosure, the switch 310 may be open in response to the second binary level, namely, the output 313 may be electrically decoupled from the input when the clock terminal 602 provides the first binary level 510 to the switch 310. Nonetheless, the logic state stored (or retained or isolated) in the second latch circuit 312 (prior to powering down the first latch circuit) may remain stored in the second latch circuit 312, in that the logic state in the second latch circuit 312 continues circulating between the second forward inverter 314 and the second feedback inverter 316 of the second latch circuit 312.

In an aspect of this disclosure where the clock terminal 602 is configured to provide a periodic binary clock signal, the binary level provided by the clock terminal to the switch 310 after the second binary level may be the first binary level. In this aspect, the switch 310 is closed upon the switch 310 receiving the first binary level, and the logic state circulating in the second latch circuit 312 is subsequently written into the first latch circuit 304, as described in FIG. 6. Accordingly, the logic state stored in the second latch circuit 312 is restored to the first latch circuit 304 without the need for an additional storage node, such as e.g. a balloon latch or a shadow latch, or additional timing overhead, such as, requiring the clock signal to be either “0” or “1”.

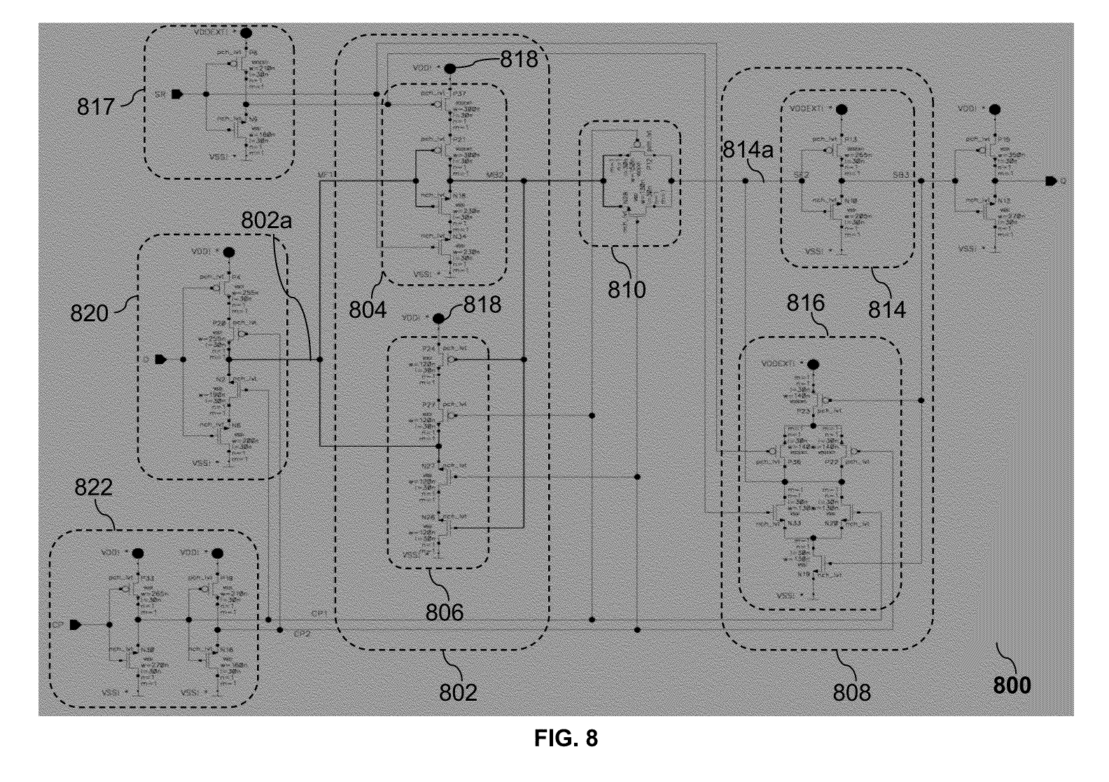

The various features described in respect of various aspects of the disclosure regarding a circuit arrangement are equally applicable to the specific case of a retention flip-flop. Accordingly, FIG. 8 shows a retention flip-flop according to various aspects of this disclose.

Various aspects of this disclosure provide a retention flip-flip 800. In an aspect of this disclosure, the retention flip-flop 800 may include a master circuit 802 which may include a first forward inverter 804 and a first feedback inverter 806. The further features described above with reference to the first latch circuit of the circuit arrangement, and its first forward and feedback inverters are equally applicable, and hereby restated, in respect of the master circuit 802 of the retention flip-flop, and its first forward and feedback inverters 804, 806, respectively.

In an aspect of this disclosure, the retention flip-flop 800 may further include a slave circuit 808. The further features described above with reference to the second latch circuit of the circuit arrangement are equally applicable, and hereby restated, in respect of the slave circuit 808 of the retention flip-flop 800.

In various aspects of this disclosure, the retention flip-flop 800 may include a transmission gate 810 coupled between an output of the first forward inverter 804 and an input of the slave circuit 808. The further features described above with reference to the switch of the circuit arrangement are equally applicable, and hereby restated, in respect of the transmission gate 810 of the retention flip-flop 800.

The retention flip-flop 800 may include an isolating circuit configured to controllably isolate the first forward inverter 804 from the first feedback inverter 806. The further features described above with reference to the isolating circuit of the circuit arrangement are equally applicable, and hereby restated, in respect of the isolating circuit of the retention flip-flop 800. In particular, as stated above in respect of the circuit arrangement, the isolating circuit may be implemented with the first forward inverter 804 as a tri-state inverter. Accordingly, as shown in FIG. 8, the forward inverter 804 may be a tri-state inverter, wherein the output of the first forward inverter 804 may assume a high impedance state such that the first forward inverter 804 is electrically decoupled from the first feedback inverter 802 and the transmission 810.

In various aspects of this disclosure, the slave circuit 808 may include a second forward inverter 814 and a second feedback inverter 816, wherein an input 814a of the second forward inverter 814 may be coupled to the transmission gate 810. The further features described above with reference to the second latch circuit of the circuit arrangement are equally applicable, and hereby restated, in respect of the slave circuit 808 of the retention flip-flop 800.

The retention flip-flop 800 may further include a power supply terminal 818 coupled to the master circuit 802, wherein the power supply terminal 818 may be configured to selectively supply power to the master circuit 802. The further features described above with reference to the power supply terminal of the circuit arrangement are equally applicable, and hereby restated, in respect of the power supply terminal 818 of the retention flip-flop 800.

The retention flip-flop 800 may include a control signal terminal 817 coupled to the isolating circuit 812, wherein the control signal terminal 818 may be configured to provide a control signal to the isolating circuit 812 to controllably isolate the first forward inverter 804 from the first feedback inverter 806. The further features described above with reference to the control signal terminal 818 of the circuit arrangement are equally applicable, and hereby restated, in respect of the control signal terminal 817 of the retention flip-flop 800.

In an aspect of this disclosure, the control signal terminal 817 may be configured to provide a restore signal to the isolating circuit 812 to electrically isolate the first forward inverter 804 from the first feedback inverter 806. The further features described above with reference to the restore signal provided by control signal terminal of the circuit arrangement are equally applicable, and hereby restated, in respect of the restore signal provided by the control signal terminal 817 of the retention flip-flop 800.

The control signal terminal 817 may be configured to provide a save signal to the isolating circuit 812 to couple the first forward inverter 804 to the first feedback inverter 806. The further features described above with reference to the save signal provided by control signal terminal of the circuit arrangement are equally applicable, and hereby restated, in respect of the save signal provided by the control signal terminal 817 of the retention flip-flop 800.

In an aspect of this disclosure, the retention flip-flop 800 may include a logic terminal 820 coupled to an input 802a of the master circuit 802. The logic terminal 820 may be further coupled to the slave circuit 808 through the input 802a and first forward inverter 804 of the master circuit 802, and the transmission gate 810 after the control signal terminal 817 has provided the save signal to the isolating circuit 812 to electrically couple the first forward inverter 804 to the first feedback inverter 806. The further features described above with reference to the logic terminal of the circuit arrangement are equally applicable, and hereby restated, in respect of the logic terminal 820 of the retention flip-flop 800.

The logic terminal 820 may be configured to provide a logic state to the slave circuit 808 through the input 802a of the master circuit 802, the first forward inverter 804, and the transmission gate 810.

The slave circuit 808 may be configured to store the logic state provided by the logic terminal 820 to the slave circuit 808, wherein storing the logic state in the slave circuit 808 may include circulating the logic state between the second forward inverter 814 and the second feedback inverter 816 of the slave circuit 808. The further features described above with reference to storing the logic state in the slave circuit 808 of the circuit arrangement are equally applicable, and hereby restated, in respect of storing the logic state in the slave circuit 808 of the retention flip-flop 800.

The power supply terminal 818 may be configured to disrupt power to the master circuit 802 after the slave circuit 808 has stored the logic state provided by the logic terminal 820 to the slave circuit 808. The further features described above with reference to the power supply terminal of the circuit arrangement are equally applicable, and hereby restated, in respect of the power supply terminal 818 of the retention flip-flop 800.

In an aspect of this disclosure, the power supply terminal 818 may resume power to the master circuit 802. In this case, the control signal terminal 817 may be configured to provide the restore signal to the isolating circuit to isolate the first forward inverter 804 from the first feedback inverter 806 after the power supply terminal 818 resumes power to the master circuit 802. The further features described above with reference to the control signal terminal of the circuit arrangement are equally applicable, and hereby restated, in respect of the control signal terminal 817 of the retention flip-flop 800.

The retention flip-flop 800 may include a clock terminal 822 coupled to the transmission gate 810. The clock terminal 822 may be configured to supply a binary clock signal including a first binary level and a second binary level to the transmission gate 810.

The transmission gate 810 may be transparent in response to the first binary level. As used herein, ‘transparent’ may mean that a signal at a first terminal of the transmission gate 810 is immediately propagated to a second terminal of the transmission date 810. Stated differently, a transparent transmission gate coupled between a first device and a second device electrically couples the first device to the second device.

In an aspect of this disclosure, the transmission gate 810 may be opaque in response to the second binary level. As used herein, ‘opaque’ may mean that a signal at a first terminal of the transmission gate 810 is not propagated to a second terminal of the transmission date 810. Stated differently, an opaque transmission gate 810 coupled between a first device and a second device electrically decouples the first device from the second device.

The slave circuit 808 may be coupled to the input 802a of the master circuit 802 through the transmission gate 810 and the first feedback inverter 806 when the clock terminal 817 provides the first binary level to the transmission gate 810. The slave circuit 808 may be configured to propagate a logic state from the slave circuit 808 to the input 802a of the master circuit 802 through the second feedback inverter 816, the transmission gate 810 and the first feedback inverter 806. The further features described above with reference to the second latch circuit of the circuit arrangement are equally applicable, and hereby restated, in respect of the slave circuit 808 of the retention flip-flop 800.

In an aspect of this disclosure, the slave circuit 808 may be decoupled from the master circuit 802 when the clock terminal 817 provides the second binary level to the transmission gate 810. The slave circuit 808 may be configured to store a logic state when the slave circuit 808 is decoupled from the master circuit 802, wherein storing the logic state in the slave circuit 808 includes circulating the logic state between the second forward inverter 814 and the second feedback inverter 816 of the slave circuit 808. The further features described above with reference to the second latch circuit of the circuit arrangement are equally applicable, and hereby restated, in respect of the slave circuit 808 of the retention flip-flop 800 decoupled from the master circuit 802.

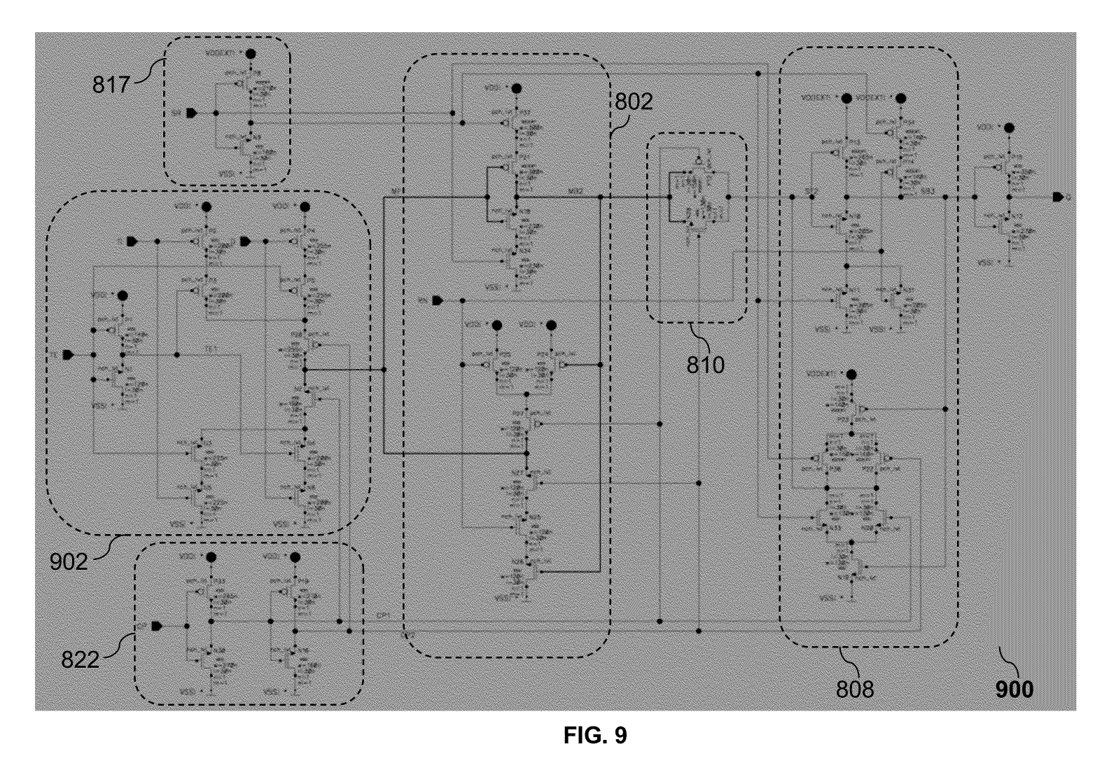

FIG. 9 shows a retention flip-flop 900 according to various aspects of this disclosure. The retention flip-flop 900 may include a logic terminal 902 which may include additional scan and reset functionality, thus allowing the retention flip-flop 900 to behave as a normal scan and reset flip-flop combined with retention capability. This feature of the retention flip-flop 900 is equally applicable to the above-described circuit arrangement. Accordingly, a similar combined functionality of scan-reset with retention capability may be available for the aforementioned circuit arrangement.

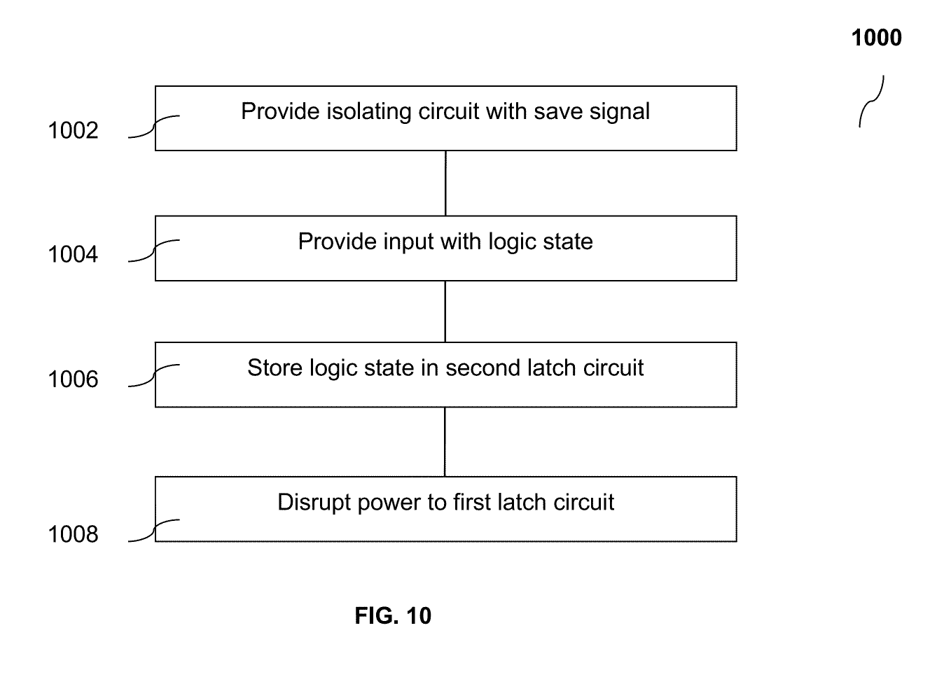

Various exemplary aspects of this disclosure provide a method for operating a circuit arrangement. FIG. 10 shows a method for operating a circuit arrangement according to various aspects of this disclosure.

The circuit arrangement may include an input; a first latch circuit coupled to the input, the first latch circuit including a first forward inverter and a first feedback inverter; a switch, wherein a first terminal of the switch is coupled to an output of the first forward inverter; a second latch circuit coupled to a second terminal of the switch; an output coupled to the second latch circuit; and an isolating circuit configured to controllably isolate the first forward inverter from an input of the first feedback inverter.

In various aspects of this disclosure, the method 1000 may include providing the isolating circuit with a save signal (in 1002), e.g. to couple the first forward inverter to the input of the first feedback inverter; providing the input with a logic state (in 1004), e.g. wherein the logic state at the input may propagate to the output through the input, the first forward inverter, the switch, and the second latch circuit; storing the logic state (e.g. at the output) in the second latch circuit (in 1006); and disrupting power to the first latch circuit (in 1008), e.g. after the second latch circuit has stored the logic state.

Providing the isolating circuit with the save signal (e.g. in 1002) may include transmitting the save signal through a control signal terminal coupled to the isolating circuit. Accordingly, the control signal terminal may provide the save signal to the isolating circuit directly or through intermediary devices, such that the control signal terminal and the isolating circuit are coupled.

Providing the input with the logic state (e.g. in 1004) may include transmitting the logic state through a logic terminal coupled to the input; and storing the logic state (e.g. at the output) in the second latch circuit (e.g. in 1006) may include circulating the logic state within the second latch circuit.

The further features described above with reference to the physical features of the circuit arrangement are equally applicable, and hereby restated, in respect of the method for operating the circuit arrangement using these physical features.

The above method 1000 may be a simple control sequence that may be employed to save data in the second latch circuit of the above-mentioned circuit arrangement.

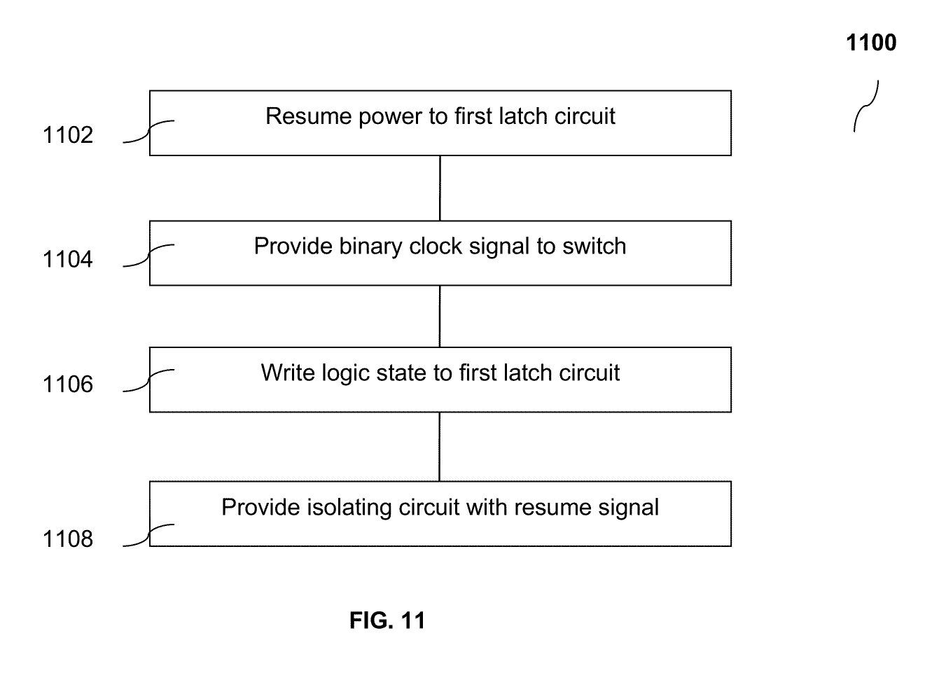

FIG. 11 shows a method 1100 for operating the above-mentioned circuit arrangement according to various aspects of this disclosure.

The method 1100 may include: resuming power to the first latch circuit (in 1102); providing a binary clock signal to the switch (in 1104), e.g. wherein the switch may be closed in response to a first binary level, and e.g. wherein the switch may be open in response to a second binary level; writing a logic state (e.g. stored in the second latch circuit) into the first latch circuit (in 1106); and providing the isolating circuit with a resume signal (in 1108), e.g. to reconnect the first forward inverter with the input of the first feedback inverter.

Providing the binary clock signal to the switch (e.g. in 1104) may include transmitting the binary clock signal through a clock signal terminal coupled to the switch.

Writing the logic state (e.g. stored in the second latch circuit) into the first latch circuit (e.g. in 1106) may include providing the first latch circuit with the logic state stored in the second latch circuit when the switch is closed in response to the first binary level, e.g. wherein the logic state stored in the second latch circuit may propagate to the first latch circuit through the switch and the first feedback inverter to the input of the first forward inverter.

Furthermore, writing the logic state (e.g. stored in the second latch circuit) into the first latch circuit (e.g. in 1106) may further include storing the logic state stored in the second latch circuit when the switch is open in response to the second binary level, and subsequently providing the first latch circuit with the logic state when the switch is closed in response to the first binary level.

Providing the isolating circuit with the resume signal (e.g. in 1108) may include transmitting the resume signal through the control signal terminal coupled to the isolating circuit. The control signal terminal may provide the restore signal to the isolating circuit directly or through intermediary devices, such that the control signal terminal and the isolating circuit are coupled. The resume signal may, for example, be suitable for reconnecting the first forward inverter with the input of the first feedback inverter.

The further features described above with reference to the physical features of the circuit arrangement are equally applicable, and hereby restated, in respect of the method for operating the circuit arrangement using these physical features.

In an aspect of this disclosure, the above method 1100 may be a simple control sequence that may be employed to write data in the first latch circuit independent of the clock level, and with low area and timing overhead.

As shown in FIG. 11, providing the binary clock signal to the switch (in 1104) and/or writing the logic state (e.g. stored in the second latch circuit) into the first latch circuit (in 1106) may occur between resuming power to the first latch circuit (in 1102) and providing the isolating circuit with a resume signal (in 1108) without the stored data being lost.

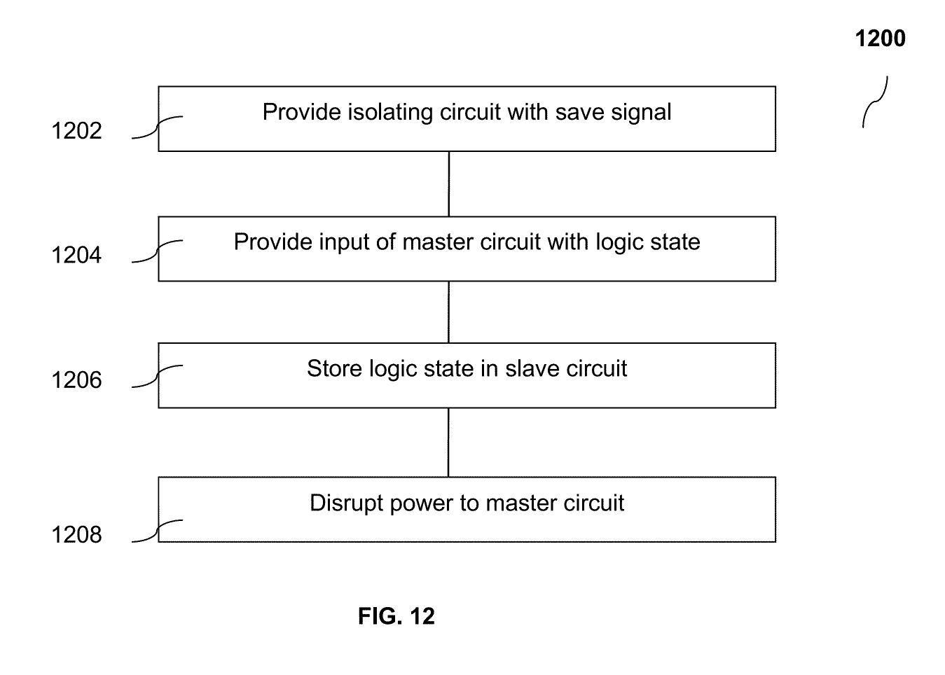

Various aspects of this disclosure provide a method for a retention flip-flop. FIG. 12 shows a method 1200 for operating a retention flip-flop according to various aspects of this disclosure.

The retention flip-flop may include a master circuit including a first forward inverter and a first feedback inverter; a slave circuit; a transmission gate coupled between an output of the first forward inverter and an input of the slave circuit; an isolating circuit configured to controllably isolate the first forward inverter from the first feedback inverter.

The method 1200 for operating a retention flip-flop may include: providing the isolating circuit with a save signal (in 1202), e.g. to couple the first forward inverter to the first feedback inverter; providing an input of the master circuit with a logic state (in 1204), e.g. wherein the logic state at the input of the master circuit may propagate to the slave circuit through the input of the master circuit, the first forward inverter, the transmission gate; storing the logic state in the slave circuit (in 1206); and disrupting power to the master circuit (in 1208), e.g. after the slave circuit has stored the logic state.

Providing the isolating circuit with the save signal (e.g. in 1202) may include transmitting the save signal through a control signal terminal coupled to the isolating circuit. Accordingly, the control signal terminal may provide the save signal to the isolating circuit directly or through intermediary devices, such that the control signal terminal and the isolating circuit are coupled.

In an aspect of this disclosure, providing the input of the master circuit with the logic state (e.g. in 1204) may include transmitting the logic state through a logic terminal coupled to the master circuit.

Storing the logic state in the slave circuit (e.g. in 1206) may include circulating the logic state within the slave circuit.

The further features described above with reference to the physical features of the retention flip-flop are equally applicable, and hereby restated, in respect of the method for operating the retention flip-flop using these physical features.

The above method 1200 may be a simple control sequence that may be employed to save data in the slave circuit of the above-mentioned retention flip-flop.

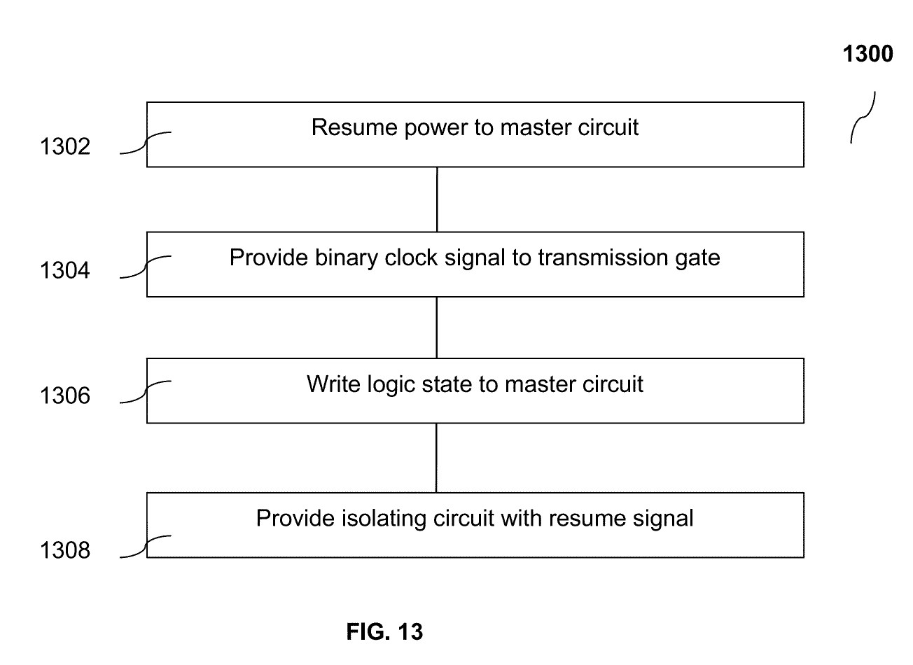

FIG. 13 shows a method 1300 for operating a retention flip-flop according to various aspects of this disclosure.

The method 1300 may include: resuming power to the master circuit (in 1302); providing a binary clock signal to the transmission gate (in 1304), e.g. wherein the transmission gate may be transparent in response to a first binary level, and e.g. wherein the transmission gate may be opaque in response to a second binary level; writing a logic state (e.g. stored in the slave circuit) into the master circuit (in 1306); and providing the isolating circuit with a resume signal (in 1308), e.g. to reconnect the first forward inverter with the input of the first feedback inverter;.

Providing the binary clock signal to the transmission gate (e.g. in 1304) may include transmitting the binary clock signal through a clock signal terminal coupled to the transmission gate.

Writing the logic state (e.g. stored in the slave circuit) into the master circuit (e.g. in 1306) may include providing the master circuit with the logic state stored in the slave circuit when the transmission gate is transparent in response to the first binary level, e.g. wherein the logic state stored in the slave circuit may propagate to the master circuit through the transmission gate and the first feedback inverter to the input of the first forward inverter.

Writing the logic state stored in the slave circuit into the master circuit (e.g. in 1306) may further include storing the logic state stored in the slave circuit when the transmission gate is opaque in response to the second binary level, and subsequently providing the master circuit with the logic state when the transmission gate is transparent in response to the first binary level.

Providing the isolating circuit with the resume signal (e.g. in 1308) may include transmitting the resume signal through the control signal terminal coupled to the isolating circuit. The resume signal may, for example, be suitable for reconnecting the first forward inverter with the input of the first feedback inverter.

The further features described above with reference to the physical features of the retention flip-flop are equally applicable, and hereby restated, in respect of the method for operating the retention flip-flop using these physical features.

The above method 1300 may be a simple control sequence that may be employed to write data in the master circuit independent of the clock level, and with low area and timing overhead.

As shown in FIG. 13, providing the binary clock signal to the transmission gate (in 1304) and/or writing the logic state (e.g. stored in the slave circuit) into the master circuit (in 1306) may occur between resuming power to the master circuit (in 1302) and providing the isolating circuit with the resume signal (in 1308) without the stored data being lost.

While various aspects of this disclosure have been particularly shown and described with reference to these aspects of this disclosure, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A circuit arrangement, comprising:
an input;
a first latch circuit coupled to the input, the first latch circuit comprising a first forward inverter and a first feedback inverter;
a switch, wherein a first terminal of the switch is coupled to an output of the first forward inverter;
a second latch circuit coupled to a second terminal of the switch;
an output coupled to the second latch circuit; and
an isolating circuit configured to isolate the first forward inverter from an input of the first feedback inverter.

2. The circuit arrangement according to claim 1,
wherein the isolating circuit is configured to controllably isolate the first forward inverter from the input of the first feedback inverter.

3. The circuit arrangement according claim 1, the second latch circuit further comprising:
a second forward inverter and a second feedback inverter, wherein an input of the second forward inverter is coupled to the second terminal of the switch, and
wherein an output of the second forward inverter is coupled to the output.

4. The circuit arrangement according claim 1, further comprising:
a power supply terminal coupled to the first latch circuit, the power supply terminal configured to selectively supply power to the first latch circuit; and
a control signal terminal coupled to the isolating circuit, the control signal terminal configured to provide a control signal to the isolating circuit to controllably isolate the first forward inverter from the input of the first feedback inverter.

5. The circuit arrangement according to claim 4,
wherein the control signal terminal is configured to provide a restore signal to the isolating circuit to isolate the first forward inverter from the input of the first feedback inverter, and
wherein the control signal terminal is configured to provide a save signal to the isolating circuit to couple the first forward inverter to the input of the first feedback inverter.

6. The circuit arrangement according to claim 5,
wherein the input is coupled to the output through the first forward inverter, the switch, and the second latch circuit after the control signal terminal has provided the save signal to the isolating circuit.

7. The circuit arrangement according to claim 5,
wherein the control signal terminal is configured to provide the restore signal to the isolating circuit to isolate the first forward inverter from the input of the first feedback inverter after the power supply terminal resumes power to the first latch circuit.

8. The circuit arrangement according claim 7, further comprising:
a clock terminal coupled to the switch, the clock terminal configured to supply a binary clock signal comprising a first binary level and a second binary level to the switch, wherein the switch is closed in response to the first binary level, and
wherein the switch is open in response to the second binary level.

9. The circuit arrangement according to claim 8,
wherein the output is coupled to the input through the second latch circuit, the switch, and the first feedback inverter when the clock terminal provides the first binary level to the switch.

10. The circuit arrangement according to claim 9,
wherein the output is configured to propagate a logic state from the output to the input through the second latch circuit, the switch, and the first feedback inverter.

11. A retention flip-flip, comprising:
a master circuit comprising a first forward inverter and a first feedback inverter;
a slave circuit;
a transmission gate coupled between an output of the first forward inverter and an input of the slave circuit;
an isolating circuit configured to controllably isolate the first forward inverter from the first feedback inverter.

12. The retention flip-flop according to claim 11,
wherein the slave circuit further comprises a second forward inverter and a second feedback inverter;
wherein an input of the second forward inverter is coupled to the transmission gate.

13. The retention flip-flop according 12, further comprising:
a power supply terminal coupled to the master circuit, the power supply terminal configured to selectively supply power to the master circuit; and
a control signal terminal coupled to the isolating circuit, the control signal terminal configured to provide a control signal to the isolating circuit to controllably isolate the first forward inverter from the first feedback inverter.

14. The retention flip-flop according to claim 13,
wherein the control signal terminal is configured to provide a restore signal to the isolating circuit to isolate the first forward inverter from the first feedback inverter, and
wherein the control signal terminal is configured to provide a save signal to the isolating circuit to couple the first forward inverter to the first feedback inverter.

15. The retention flip-flop according to claim 14, further comprising:
a logic terminal coupled to an input of the master circuit, the logic terminal further coupled to the slave circuit through the input of the master circuit, the first forward inverter, and the transmission gate after the control signal terminal has provided the save signal to the isolating circuit.

16. A method for operating a circuit arrangement,
the circuit arrangement comprising:
an input;
a first latch circuit coupled to the input, the first latch circuit comprising a first forward inverter and a first feedback inverter;
a switch, wherein a first terminal of the switch is coupled to an output of the first forward inverter;
a second latch circuit coupled to a second terminal of the switch;
an output coupled to the second latch circuit; and
an isolating circuit configured to controllably isolate the first forward inverter from an input of the first feedback inverter;
the method comprising:
providing the isolating circuit with a save signal to couple the first forward inverter to the input of the first feedback inverter;
providing the input with a logic state, wherein the logic state at the input propagates to the output through the input, the first forward inverter, the switch, and the second latch circuit;
storing the logic state at the output in the second latch circuit;
disrupting power to the first latch circuit after the second latch circuit has stored the logic state.

17. The method according to claim 16, further comprising:
providing the isolating circuit with the save signal comprises transmitting the save signal through a control signal terminal coupled to the isolating circuit;
providing the input with the logic state comprises transmitting the logic state through a logic terminal coupled to the input; and
storing the logic state at the output in the second latch circuit comprises circulating the logic state within the second latch circuit.

18. The method according to claim 16, comprising:
resuming power to the first latch circuit;
providing a binary clock signal to the switch, wherein the switch is closed in response to a first binary level, and wherein the switch is open in response to a second binary level;
writing a logic state stored in the second latch circuit into the first latch circuit; and
providing the isolating circuit with a resume signal to reconnect the first forward inverter with the input of the first feedback inverter.

19. The method according to claim 18, further comprising:
writing the logic state stored in the second latch circuit into the first latch circuit comprises:
providing the first latch circuit with the logic state stored in the second latch circuit when the switch is closed in response to the first binary level, wherein the logic state stored in the second latch circuit propagates to the first latch circuit through the switch and the first feedback inverter to the input of the first forward inverter; and
storing the logic state stored in the second latch circuit when the switch is open in response to the second binary level, and subsequently providing the first latch circuit with the logic state when the switch is closed in response to the first binary level.

20. A method for operating a retention flip-flop,
the retention flip-flop comprising:
a master circuit comprising a first forward inverter and a first feedback inverter;
a slave circuit;
a transmission gate coupled between an output of the first forward inverter and an input of the slave circuit;
an isolating circuit configured to controllably isolate the first forward inverter from the first feedback inverter;
the method comprising:
providing the isolating circuit with a save signal to couple the first forward inverter to the first feedback inverter;
providing an input of the master circuit with a logic state, wherein the logic state at the input of the master circuit propagates to the slave circuit through the input of the master circuit, the first forward inverter, and the transmission gate;
storing the logic state in the slave circuit; and
disrupting power to the master circuit after the slave circuit has stored the logic state.

21. The method according to claim 20, further comprising:
providing the isolating circuit with the save signal comprises transmitting the save signal through a control signal terminal coupled to the isolating circuit;
providing the input of the master circuit with the logic state comprises transmitting the logic state through a logic terminal coupled to the master circuit; and
storing the logic state in the slave circuit comprises circulating the logic state within the slave circuit.

22. The method for operating a retention flip-flop according to claim 20, further comprising:
resuming power to the master circuit;
providing a binary clock signal to the transmission gate, wherein the transmission gate is transparent in response to a first binary level, and wherein the transmission gate is opaque in response to a second binary level;
writing a logic state stored in the slave circuit into the master circuit; and
providing the isolating circuit with a resume signal to reconnect the first forward inverter with the input of the first feedback inverter.

23. The method according to claim 22, further comprising:
providing the isolating circuit with the resume signal comprises transmitting the resume signal through the control signal terminal coupled to the isolating circuit; and
providing the binary clock signal to the transmission gate comprises transmitting the binary clock signal through a clock signal terminal coupled to the transmission gate.

24. The method according to claim 22, further comprising:
writing the logic state stored in the slave circuit into the master circuit comprises:
providing the master circuit with the logic state stored in the slave circuit when the transmission gate is transparent in response to the first binary level, wherein the logic state stored in the slave circuit propagates to the master circuit through the transmission gate and the first feedback inverter to the input of the first forward inverter; and
storing the logic state stored in the slave circuit when the transmission gate is opaque in response to the second binary level, and subsequently providing the master circuit with the logic state when the transmission gate is transparent in response to the first binary level.
